(19) United States
(12) Patent Application Publication
(10) Pub. No.: US 2017/0264237 A1
(43) Pub. Date: Sep. 14, 2017

(54) METHOD AND APPARATUS FOR SOLAR POWER GENERATION

(71) Applicant: Neotec Energy Pty. Ltd., Wilmington, DE (US)

(72) Inventor: Christoph Karl La Due, Talent, OR (US)

(21) Appl. No.: 15/391,715

(22) Filed: Dec. 27, 2016

Related U.S. Application Data
(60) Provisional application No. 62/305,446, filed on Mar. 8, 2016.

(51) Int. Cl. H02S 20/30; H01L 31/05; H02S 40/36; H02S 40/34; H02S 40/22; H01L 31/02

(52) U.S. Cl. CPC H02S 20/30; H02S 40/22; H01L 31/02008; H02S 40/36; H02S 40/34; H01L 31/0504

(57) ABSTRACT

A solar power generator with lens to receive radiant energy from the sun, a drive shaft positioned near the lens, and a motor coupled to rotate the drive shaft. Solar modules are coupled to the drive shaft, such that as the drive shaft rotates, each module receives radiant energy as it rotates by the lens and produces a voltage signal. A first circuit coupled to a first subset of the solar modules receives their voltage signals and produces therefrom a first DC voltage square wave. A second circuit coupled to a second subset of the solar modules receives their voltage signals subset and produces a second DC voltage square wave. The second circuit is electrically coupled to the first circuit such that the first DC voltage square wave and the second DC voltage square wave are combined to produce a combined DC voltage signal.

### TECHNICAL FIELD

Embodiments of the present invention relate to solar power generation.

### BACKGROUND

Flat panel solar power generators are inefficient. What is needed is an increase in power generation capability beyond present day flat panel solar generation technology, while at the same time a decrease in the footprint or size requirements for flat panel solar power generation technology.

### BRIEF DESCRIPTION OF THE DRAWINGS

The features and advantages of embodiments of the invention will become apparent from the following detailed description of the subject matter in which:

FIG. 1A illustrates a three-dimensional view of an embodiment of the invention;

FIG. 1B illustrates a three-dimensional view of an embodiment of the invention;

FIG. 2 illustrates a three-dimensional view of one embodiment of the invention in which the number facets/solar modules equals six;

FIG. 3 is a timing diagram of a DC square wave generated by an embodiment of the invention;

FIG. 4 is an electrical schematic of the switching circuits according to an embodiment of the invention; and

FIG. 5 is an electrical schematic of switching circuit and filter according to an embodiment of the invention.

### DETAILED DESCRIPTION

A solar power generator according to an embodiment of the invention is a direct current (DC) power generator in which l groups of n solar modules provide for a total of m solar modules. The embodiment comprises l groups of n solar modules mounted on a rotating hub, wired together in a proprietary circuit design, under light concentration (by way of a focusing lens), as one electrically independent DC generator. In one embodiment, each of the n solar modules comprises a side, or facet, of the n solar modules when mounted on the rotating hub, and each of the n solar modules produces a DC pulse, such as a three-volt (3V) DC pulse. In one embodiment of the solar power generator, n=6, providing a six-sided (hexagonal) spinning form factor. However, other embodiments are contemplated in which the number of solar modules, n, =2, 3, 4, 5, 8, 10, 12, etc. For example, in another embodiment, the number of modules, n, =8, providing an octagonal spinning form factor. In any embodiment, each n faceted DC power generator operates as a constant voltage DC generator in which amperage output, and therefore power in watts, is directly proportional to the level of solar concentration.

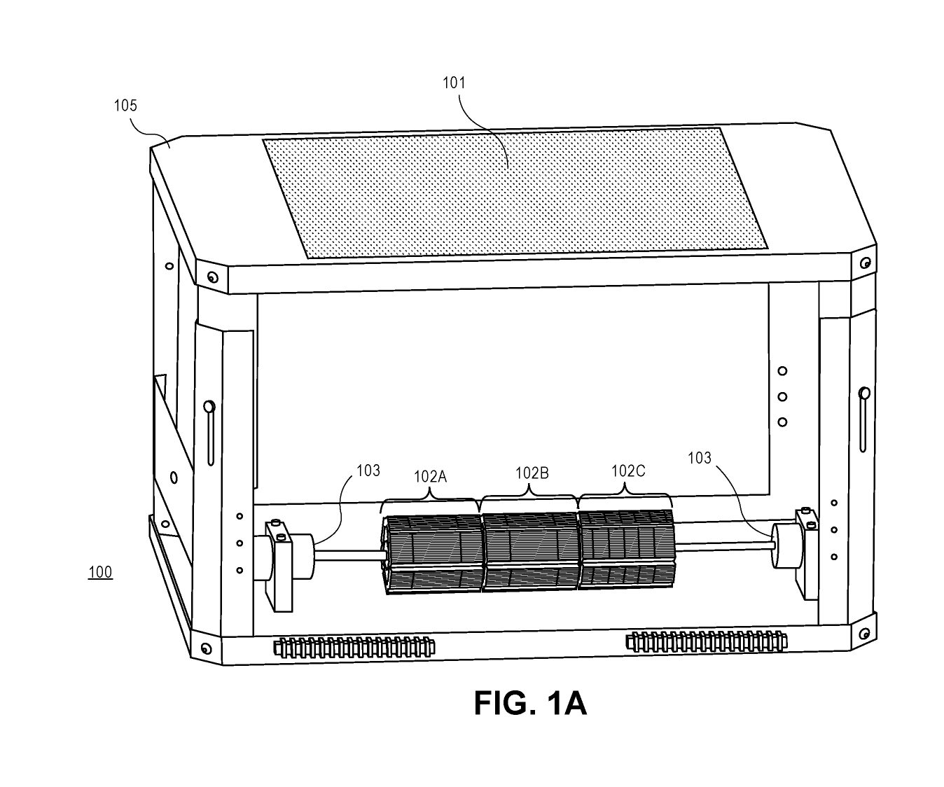

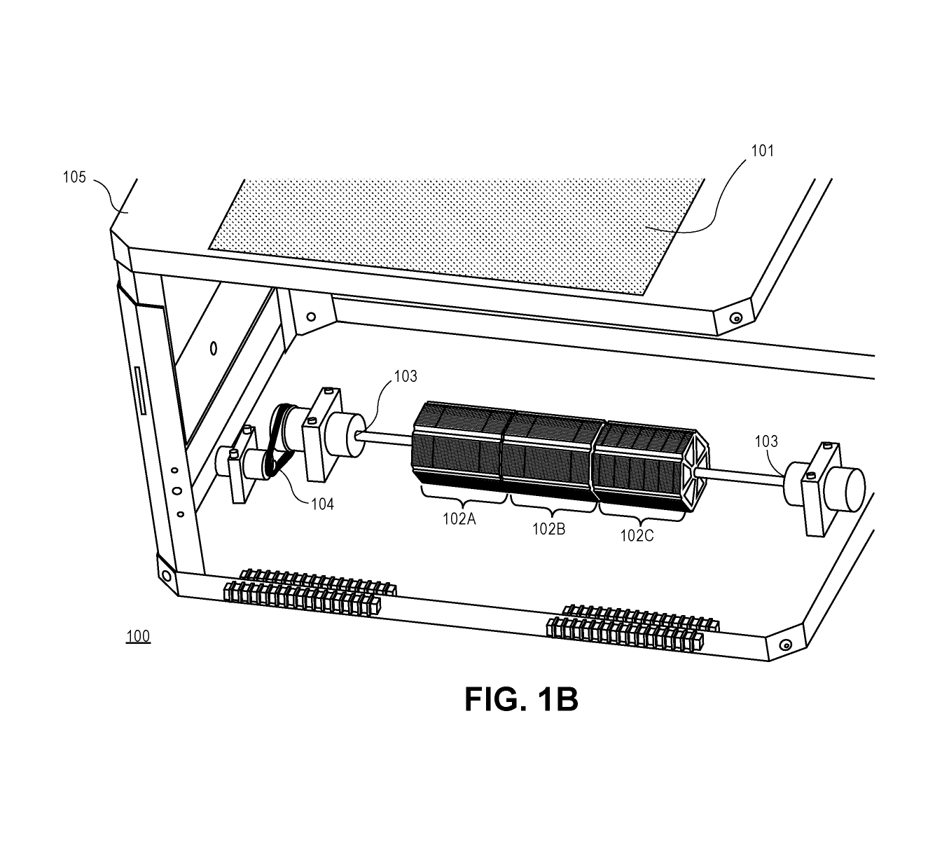

FIGS. 1A and 1B illustrate the basic components of an embodiment 100 of the invention. A lens, e.g., a linear Fresnel lens 101, concentrates sunlight across l groups of DC generators 102A, 102B, 102C, in which l=3. In the embodiment, two 16-channel slip rings 103 are utilized to electrically couple each facet (solar module) to a respective charging or switching circuit. The 3 DC generators (3) rotate at exactly the same RPM. A drive axle DC motor 104 rotates the three DC generators at a selected RPM, such as 150 RPM. A chassis 105 accommodates a lens, such as a linear Fresnel lens 101 and other components. While l=3 in the illustrated embodiment, other embodiments may include one DC generator, or a plurality of groups other than 3 DC generators. In the embodiments further discussed below, any features described with respect to a single DC generator embodiment apply to embodiments in which the number of groups of DC generators, l, is more than one.

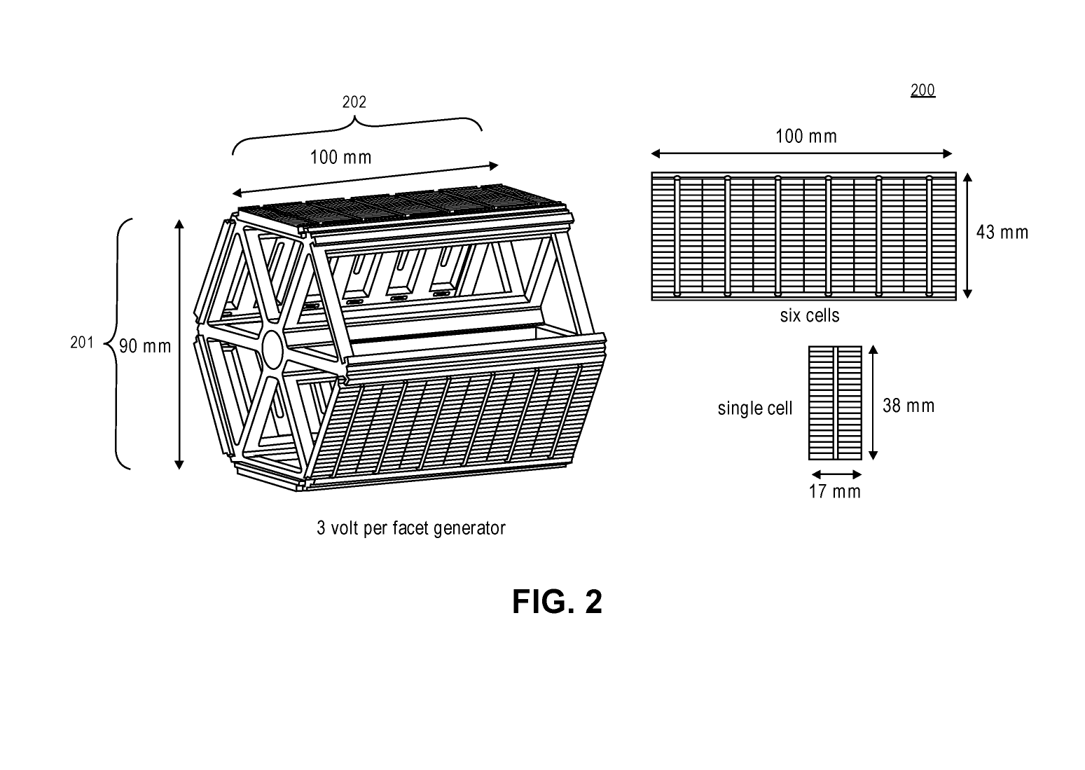

FIG. 2 illustrates an embodiment 200 in which the number of solar modules, n, =6, providing a six-sided (hexagonal) spinning form factor 201. Furthermore, each solar module comprises x individual photovoltaic cells 202. In the illustrated embodiment, x=6, but in other embodiments, x may equal one or more photovoltaic cells per solar module. In an embodiment such as illustrated where x>1, the individual photovoltaic cells within each of the n solar modules are wired in series to obtain a particular or desired voltage output, such as 3V. Thus, in the illustrated embodiment, the number of photovoltaic cells, x, =6 for each side (solar module) of the spinning hexagonal solar power generator, and each cell generates 0.5V for a total of 3V per facet/side/solar module.

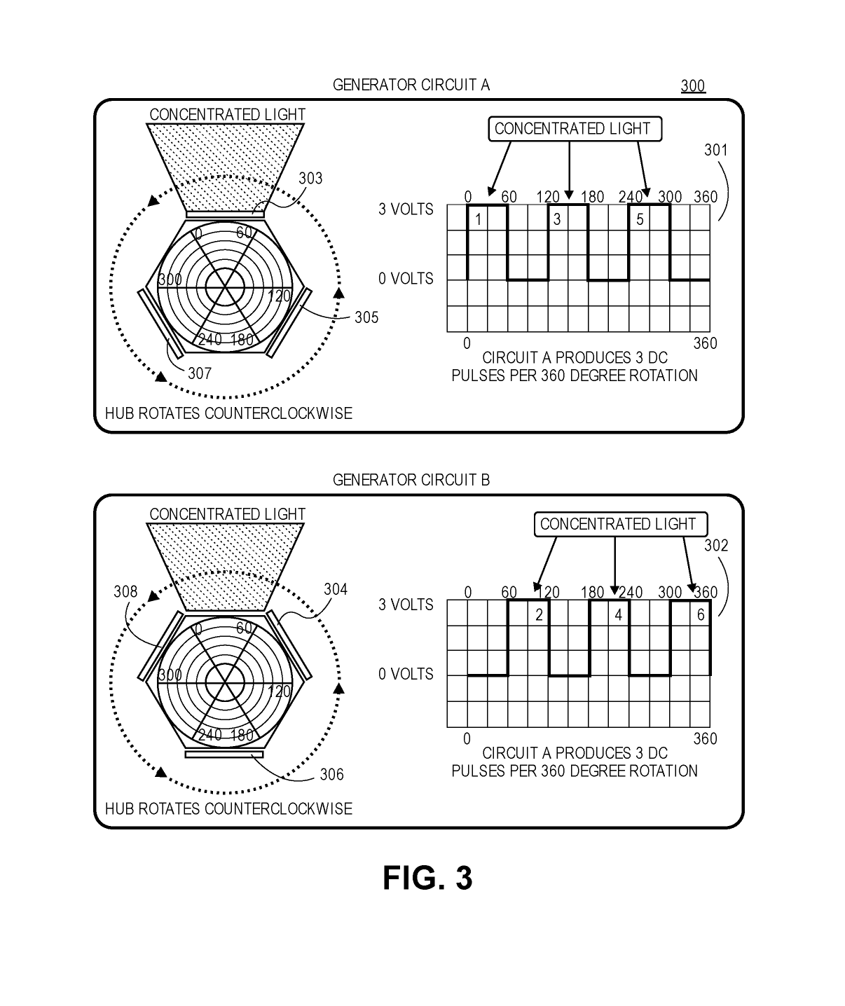

With respect to FIG. 3, in one embodiment 300, the solar power generator outputs two independent DC pulse waveforms 301 and 302. In general, and as shown in the illustrated embodiment, separate groups of nonadjacent solar modules are wired in series to produce multiple independent and separate charging circuits. In the illustrated embodiment, the number of independent charging circuits is two, and the number of solar modules per group (charging circuit) is three, but in other embodiments, a greater number of independent charging circuits may be implemented, with more or less solar modules per group (charging circuit). For example, in alternative embodiments, there may be three or more charging circuits with one or more solar modules per circuit. In embodiment 300, nonadjacent solar modules 303, 305 and 307 are electrically wired together in series to produce one independent and separate charging circuit that generates DC pulse waveform 301, and nonadjacent solar modules 304, 306 and 308 are electrically wired together in series to produce a different, independent, and separate charging circuit that generates DC pulse waveform 302.

It is thought that wiring nonadjacent solar modules together in series, in separate circuits, as opposed to wiring adjacent solar modules together in a single circuit, provides certain advantages in terms of the power being generated by the solar power generator. Furthermore, depending on the power generation application, it is appreciated that the number of and/or configuration of separate charging circuits, the number of and/or configuration of solar modules wired together and to a separate charging circuit, and the number of and/or configuration of photovoltaic cells wired together in a single solar module or facet, may be different in order to meet the needs of the particular power generation application.

Indeed, it is contemplated that the number of and configuration of separate charging circuits, the number and configuration of solar modules wired together, and/or the number of and/or configuration of photovoltaic cells wired together, for example, in series, may be changed on the fly, after installation of a solar power generator, according to an embodiment of the invention, in order to meet the needs of the particular power generation application, for example, depending on one or more of the time of day, season, weather conditions, power output needs, power generation costs and rates. In one embodiment, a particular number of l groups of n solar modules is installed, and each solar module has x photovoltaic cells capable of being electrically coupled together in any configuration of one or more independent charging circuits including one or more adjacent or nonadjacent solar modules. A switching matrix and microcontroller may be included in the embodiment of the invention, the matrix coupled to the individual switching/charging circuits and/or solar modules and/or photovoltaic cells, and the microcontroller coupled to the switching matrix. Executable code may be loaded into the microcontroller at an appropriate time (e.g., at installation or as an update to an already installed and operating solar power generator). When executed by the microcontroller, the executable code allows for (re)configuration of the l groups of n solar modules of x photovoltaic cells, the number and/or configuration of switching/charging circuits, and/or the number and configuration of solar modules within each charging circuit, and the number and configuration of photovoltaic cells within each solar module, for example, based on user input and/or external factors determined and input by sensors that detect external conditions such as time of day, temperature, weather, power output needs, power generation costs and rates. The user input and/or external factors, in turn, may be automatic or manual, and may be based on circumstances such as mentioned above, including time of day, season, weather conditions, power generation needs, power generation costs, and power generation consumer rates.

In the l=1 DC generator embodiment illustrated in FIG. 3, n=6 solar modules, and x=6 photovoltaic cells per module. Further, there are two independent DC switching, or charging, circuits, in which nonadjacent cells 303, 305 and 307 are wired together in series in a first charging circuit (A), and in which nonadjacent cells 304, 306, and 308 are wired together in series in a second charging circuit (B) independent and separate from the first charging circuit. As the hexagonal configuration of solar modules mounted on the rotating hub rotate by the lens and receive concentrated light from the sun, each module generates a DC pulse waveform as shown in FIG. 3 at 301 and 302, wherein the DC pulse waveform 301 is 180 degrees out-of-phase with respect to DC pulse waveform 302.

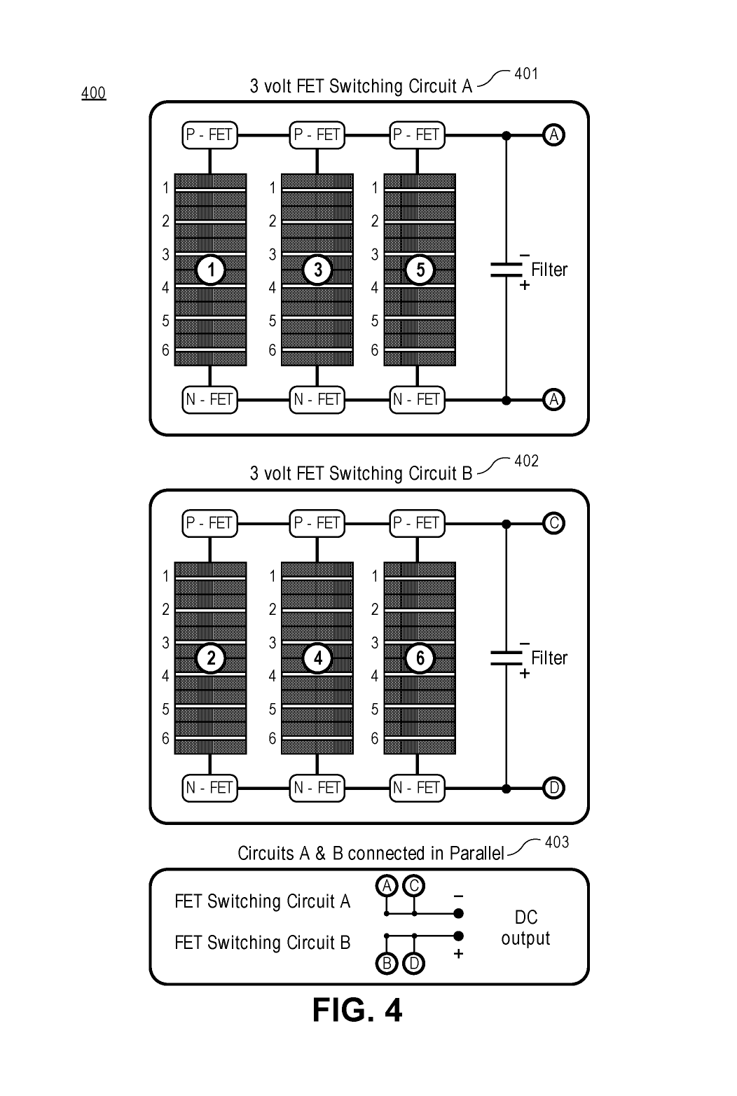

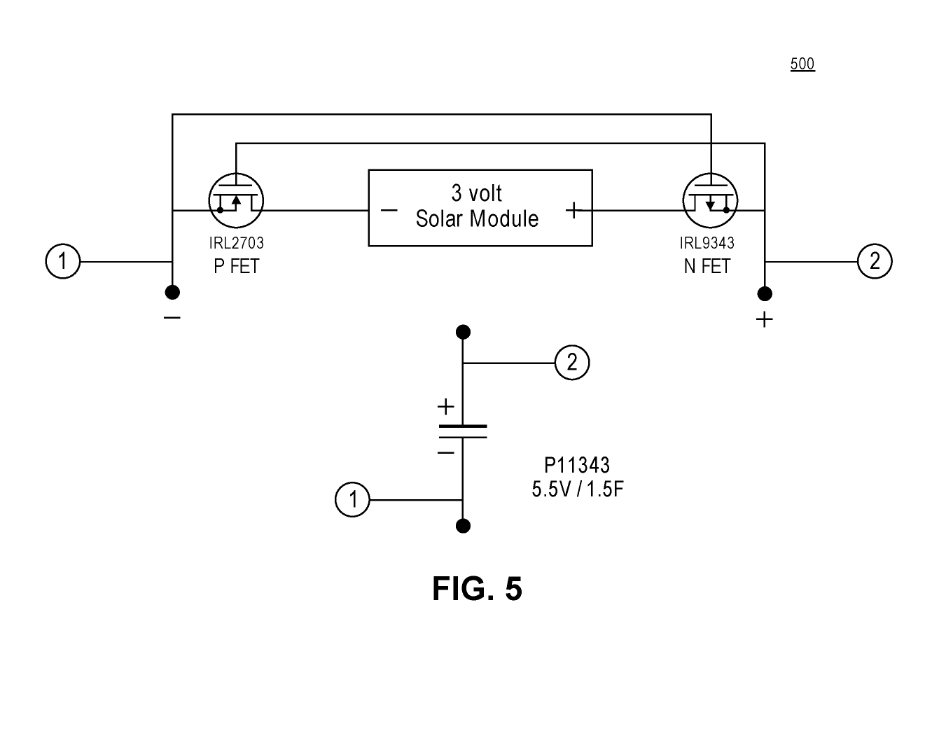

One embodiment of the invention combines the separate DC pulse waveforms into a single, steady state, DC, signal. FIG. 4 illustrates an embodiment of the invention 400 in which the separate switching, or charging, circuits A (401) and B (402), are coupled in parallel as indicated at 403. The switches, e.g, P-FETs and N-FETs illustrated in the figure, prevent reverse current in each 3V switching circuit when the solar modules are not illuminated with concentrated light under the lens. Circuits A and B are coupled together in parallel as illustrated to convert the separate DC pulse waveform generated by circuits A and B into a single steady state, or constant, 3V DC signal. FIG. 5 provides further details of one embodiment 500 in which an individual solar module is coupled to the FET switching circuit of FIG. 4 in such a manner as to generate a DC pulse.

Thus, in one embodiment, a solar power generator, comprises a lens through which to receive radiant energy from the sun; a drive shaft is positioned near the lens; a motor is coupled to the drive shaft a rotate the drive shaft; a plurality of solar modules is coupled to the drive shaft, such that as the motor rotates the drive shaft, each one of the plurality of solar modules receives radiant energy as it rotates by the lens and produces therefrom a voltage signal; a first circuit is coupled to a first subset of the plurality of solar modules to receive the voltage signals produced by each solar module in the first subset and produce therefrom a first DC voltage square wave; and a second circuit is coupled to a second subset of the plurality of solar modules to receive the voltage signals produced by each solar module in the second subset and produce a second DC voltage square wave; and the second circuit is electrically coupled to the first circuit such that the first DC voltage square wave and the second DC voltage square wave are combined to produce a combined DC voltage signal.

In one embodiment, the solar power generator of claim 1, wherein the combined DC voltage signal is a constant DC voltage signal. In another embodiment, the combined DC voltage signal may be further combined with other DC voltage signals produce by yet other solar modules to generate a constant DC voltage signal.

In one embodiment of the solar power generator of claim 1, the first subset of the plurality of solar modules comprises one or more than one nonadjacent solar module, and the second subset of the plurality of solar modules comprises one or more than one nonadjacent solar module different from the first subset.

In one embodiment of the solar power generator, the first circuit and the second circuit each comprises circuitry to positively clamp the respectively received voltage signal so that there is no negative voltage component in the respectively produced DC voltage square wave. In one embodiment, the second DC voltage square wave is 180 degrees out-of-phase with respect to the first DC voltage square wave. The solar power generator in one embodiment further comprises a slip ring via which the first circuit is coupled to the first subset of the plurality of solar modules and via which the second circuit is coupled to the second subset of the plurality of solar modules.

One embodiment of the solar power generator comprises a plurality of photovoltaic cells electrically coupled in series for each solar module.

In one embodiment of the solar power generator, the drive shaft and the plurality of solar modules are concentric with respect to a longitudinal axis.

While the disclosed subject matter has been described with reference to illustrative embodiments, this description is not intended to be construed in a limiting sense. Various modifications of the illustrative embodiments, as well as other embodiments of the subject matter, which are apparent to persons skilled in the art to which the disclosed subject matter pertains are deemed to lie within the scope of the disclosed subject matter.

What is claimed is:

1. A solar power generator, comprising:
a lens through which to receive radiant energy from the sun;
a drive shaft positioned near the lens;
a motor coupled to the drive shaft to rotate the drive shaft;
a plurality of solar modules coupled to the drive shaft, such that as the motor rotates the drive shaft, each one of the plurality of solar modules receives radiant energy as it rotates by the lens and produces therefrom a voltage signal;
a first circuit coupled to a first subset of the plurality of solar modules to receive the voltage signals produced by each solar module in the first subset and produce therefrom a first DC voltage square wave; and
a second circuit coupled to a second subset of the plurality of solar modules to receive the voltage signals produced by each solar module in the second subset and produce a second DC voltage square wave, the second circuit electrically coupled to the first circuit such that the first DC voltage square wave and the second DC voltage square wave are combined to produce a combined DC voltage signal.

2. The solar power generator of claim 1, wherein the combined DC voltage signal is a constant DC voltage signal.

3. The solar power generator of claim 1, wherein the first subset of the plurality of solar modules comprises one or more than one nonadjacent solar module, and wherein the second subset of the plurality of solar modules comprises one or more than one nonadjacent solar module different from the first subset.

4. The solar power generator of claim 1, wherein the first circuit and the second circuit each comprises circuitry to positively clamp the respectively received voltage signal so that there is no negative voltage component in the respectively produced DC voltage square wave.

5. The solar power generator of claim 1, wherein the second DC voltage square wave is 180 degrees out-of-phase with respect to the first DC voltage square wave.

6. The solar power generator of claim 1, further comprising a slip ring via which the first circuit is coupled to the first subset of the plurality of solar modules and via which the second circuit is coupled to the second subset of the plurality of solar modules.

7. The solar power generator of claim 1, wherein each of the plurality of solar modules comprises a plurality of photovoltaic cells electrically coupled in series.

8. The solar power generator of claim 1 wherein the drive shaft and the plurality of solar modules are concentric with respect to a longitudinal axis.
